(19) United States
(12) Patent Application Publication
(10) Pub. No.: US 2022/0329323 A1
(43) Pub. Date: Oct. 13, 2022

(54) OPTICAL EMITTING DEVICE WITH BUILT-IN THERMOELECTRIC COOLER AND OPTICAL TRANSCEIVER MODULE HAVING THE SAME

(71) Applicant: Global Technology Inc., Ningbo (CN)

(72) Inventors: Jian-Hong LUO, Ningbo (CN); YiMeng XU, Ningbo (CN); Xiang ZHENG, Ningbo (CN); Fu CHEN, Ningbo (CN)

(21) Appl. No.: 17/329,887

(22) Filed: May 25, 2021

(30) Foreign Application Priority Data
Apr. 7, 2021 (CN) 202110371307.2

(51) Int. Cl. H04B 10/40; H01S 5/024; H04B 10/50

(52) U.S. Cl. CPC H04B 10/40; H01S 5/02415; H04B 10/503

(57) ABSTRACT

An optical emitting device includes a base, a thermoelectric cooler, an optical communication assembly and a circuit board. The base includes a main body and a stem connected with each other. The stem extends from a basal surface of the main body, and a normal of a supporting surface of the stem is non-parallel to a normal of the basal surface of the main body. The thermoelectric cooler is disposed on the supporting surface of the stem. The optical communication assembly is disposed on the thermoelectric cooler, and the thermoelectric cooler is between the optical communication assembly and the stem. The circuit board is disposed on the base and passes through the main body and electrically connected with the optical communication assembly.

### CROSS-REFERENCE TO RELATED APPLICATIONS

This non-provisional application claims priority under 35 U.S.C. § 119(a) on Patent Application No(s). 202110371307.2 filed in China on Apr. 4, 2021, the entire contents of which are hereby incorporated by reference.

### BACKGROUND

### 1. Technical Field

The present disclosure relates to optical communication, more particularly to an optical emitting device.

### 2. Related Art

Optical transceivers are generally installed in electronic communication facilities in modern high-speed communication networks. In order to make flexible the design of an electronic communication facility and less burdensome the maintenance of the same, an optical transceiver is inserted into a corresponding cage that is disposed in the communication facility in a pluggable manner. In order to define the electrical-to-mechanical interface of the optical transceiver and the corresponding cage, different form factors such as XFP (10 Gigabit Small Form Factor Pluggable) used in 10 GB/s communication rate, QSFP (Quad Small Form-factor Pluggable), or others at different communication rates have been made available.

As to the optical components in a conventional optical transceiver, TO (Transistor Outline)-CAN package has the advantages of small volume and excellent airtightness, so that it is widely used in the design of a single channel optical communication system.

### BRIEF DESCRIPTION OF THE DRAWINGS

The present disclosure will become more fully understood from the detailed description given below and the accompanying drawings which are given by way of illustration only and thus are not intending to limit the present disclosure and wherein:

FIG. 1 is a schematic view of an optical emitting device according to one embodiment of the present disclosure;

FIG. 2 is an exploded view of the optical emitting device in FIG. 1;

FIG. 3 is a side view of the optical emitting device in FIG. 2;

FIG. 4 is a top view of the optical emitting device in FIG. 2; and

FIG. 5 is a schematic view of an optical transceiver module according to another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

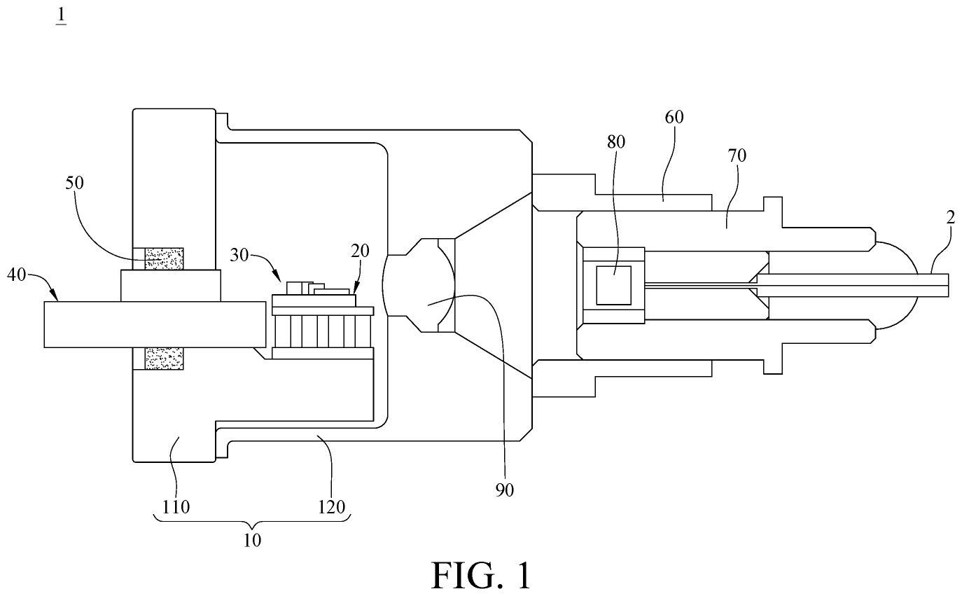

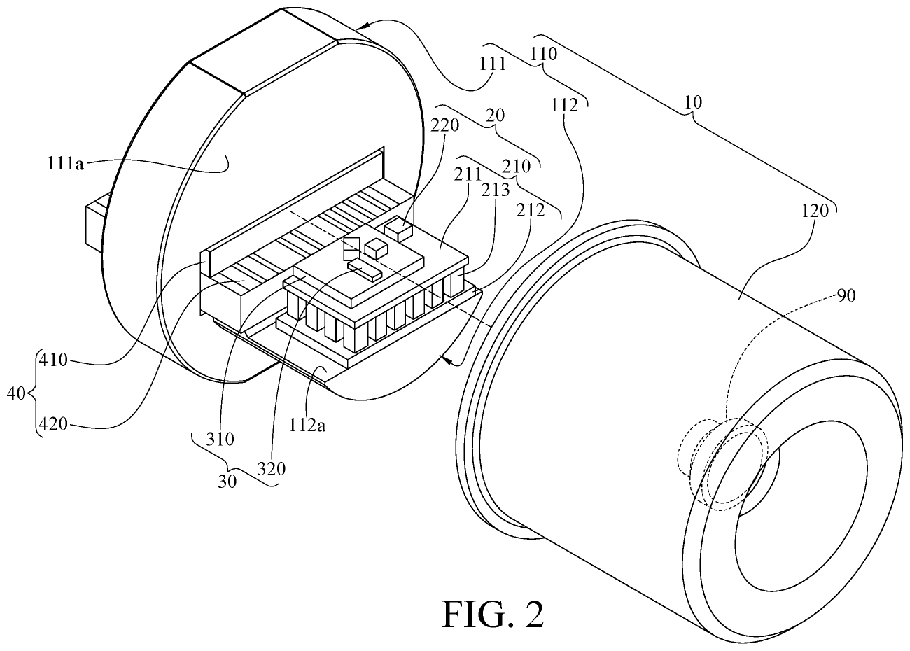

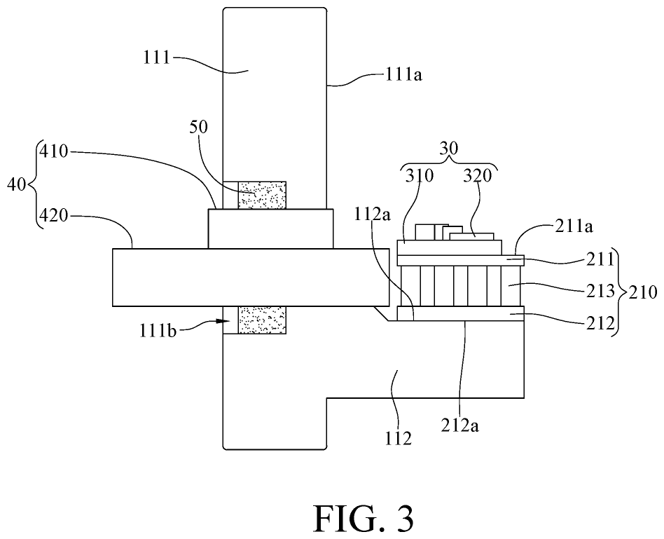

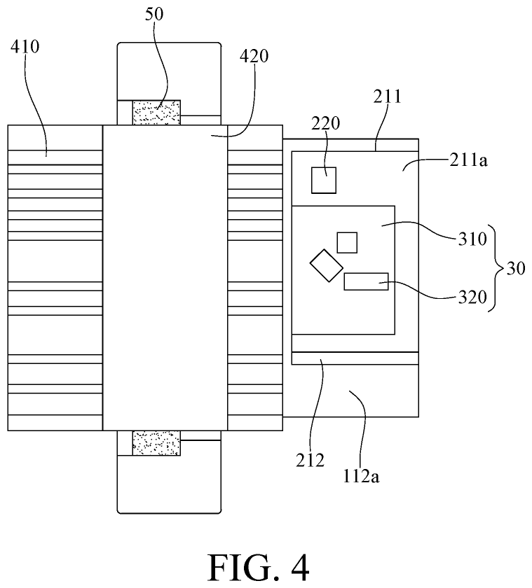

Please refer to FIG. 1 through FIG. 4. FIG. 1 is a schematic view of an optical emitting device according to one embodiment of the present disclosure. FIG. 2 is an exploded view of the optical emitting device in FIG. 1. FIG. 3 is a side view of the optical emitting device in FIG. 2. FIG. 4 is a top view of the optical emitting device in FIG. 2. In this embodiment, an optical emitting device 1 may include a casing 10, a thermoelectric cooler 20, an optical communication assembly 30 and a circuit board 40.

The casing 10 is, for example but not limited to, a casing for a TO-CAN package, and the casing 10 includes a base 110 and a cap 120. In this embodiment, the base 110 may be a header for the TO-CAN package, and the cap 120 may be a cover for the same TO-CAN package. The base 110 includes a main body 111 and a stem 112 connected with each other. The stem 112 extends from a basal surface 111a of the main body 111 toward the cap 120, and a normal of the supporting surface 112a of the stem 112 is non-parallel to a normal of the basal surface 111a of the main body 111. More specifically, normal of the supporting surface 112a may be orthogonal to the normal of the basal surface 111a. In other words, the basal surface 111a may be perpendicular to the supporting surface 112a. For the purpose of illustration, the cap 120 is omitted in FIG. 3 and FIG. 4.

The thermoelectric cooler 20 is disposed on the supporting surface 112a of the stem 112. The thermoelectric cooler 20 includes a thermoelectric component 210 and a chip temperature controller 220. The thermoelectric component 210 includes a top electrode 211, a bottom electrode 212 and a thermoelectric material 213, and the top electrode 211 and bottom electrode 212 are located on opposite sides of the thermoelectric material 213, respectively. The thermoelectric material 213 is, for example but not limited to, bismuth telluride, ytterbium silicide, Vanadium (IV) oxide or material with high electrical conductivity and low thermal conductivity. The top electrode 211 includes a cold surface 211a opposite to where the thermoelectric material 213 contacts with the top electrode 211, the bottom electrode 212 includes a hot surface 212a opposite to where the thermoelectric material 213 contacts the bottom electrode 212. Additionally, the hot surface 212a faces toward the supporting surface 112a of the stem 112. The chip temperature controller 220 is disposed on the cold surface 211a, and the hot surface 212a is in thermal contact with the supporting surface 112a. A normal of the cold surface 211a is parallel to the normal of the supporting surface 112a. Thus, in one implementation the cold surface 211a and the hot surface 212a are parallel to the supporting surface 112a and perpendicular to the basal surface 111a of the casing 10. It is worth noting that the protective scope of the present disclosure is not limited to the chip temperature controller on the cold surface of the top electrode. In some embodiments, the chip temperature controller nay be located on any region of the top electrode such as the lateral surface or the bottom surface thereof.

The optical communication assembly 30 is accommodated in the casing 10 and disposed on the thermoelectric cooler 20. The thermoelectric cooler 20 is located between the optical communication assembly 30 and the stem 112. The optical communication assembly 30 includes a submount 310 and an optical communication unit 320 disposed on the submount 310, and the submount 310 is in thermal contact with the top electrode 211 of the thermoelectric cooler 20. The submount 310 is, for example but not limited to, a printed circuit board (PCB), and the optical communication unit 320 is disposed on the top surface of the submount 310. The optical communication unit 320 is, for example but not limited to, a light emitting diode such as directly modulated laser (DML) diode, electro-absorption modulated laser (EML) diode, or other kinds of edge emitting laser diodes. The submount 310 of the optical communication assembly 30 is disposed on the cold surface 211a of the thermoelectric component 210, and the submount 310 is in thermal contact with the cold surface 211a. The thermoelectric cooler 20 could help maintain the operating temperature within a suitable range by dissipating heat generated over the course of the operation of the optical communication assembly 30 through the base 110 of the casing 10.

The circuit board 40 is disposed on the base 110 of the casing 10. More specifically, the circuit board 40 passes through the main body 111 of the base 110 and is electrically connected with the optical communication assembly 30. The main body 111 of the base 110 includes an opening 111b through which the circuit board 40 passes. The circuit board 40 may be electrically connected with the submount 310, the optical communication unit 320, the optical communication unit 320, the top electrode 211 and bottom electrode 212 of the thermoelectric cooler 20, or the chip temperature controller 220 by metal pins, flexible circuit board or wire bonding.

In this embodiment, a solder 50 may be filled in the opening 111b on the base 110 of the casing 10, and the solder 50 is, for example but not limited to, glass solder or metal solder. The circuit board 40 is fixed to the base 110 by the solder 50. In detail, the solder 50 is filled in a gap between the circuit board 40 and the main body 1110. Moreover, the circuit board 40 includes a ceramic PCB for high frequency signal transmission in this embodiment, and the circuit board 40 may include a ceramic substrate 410 and an interlayer substrate 420. The thermoelectric cooler 20 is electrically connected with the optical communication assembly 30 and the interlayer substrate 420 by, for example, wire bonding. The solder 50 is in electrical contact with the ceramic substrate 410, and join the ceramic substrate 410 with the base 110 by soldering and brazing. The solder 50 might enable the assembly of the circuit board 40 and the base 110 to meet the requirements of air tightness and structural strength, both of which could minimize the corrosion of components in the casing 10. Since the ceramic substrate 410 of the circuit board 40 is electrically insulated from the interlayer substrate 420, the signal transmission among the circuit board 40, the thermoelectric cooler 20 and the optical communication assembly 30 will not be affected even though the solder 50 is conductive. Thus, more options for the solder 50 might become available since its conductivity (or lack thereof) is no longer considered.

As shown in FIG. 1 and FIG. 2, in this embodiment, a welding ring 60 may be disposed on the cap 120 of the housing, and a fiber adaptor 70 may be inserted into the welding ring 60. More specifically, the welding ring 60 and the fiber adaptor 70 may be joined together by laser penetration welding, with the optical fiber 2 optically coupled to the optical communication assembly 30 via the fiber adaptor 70. It is worth noting that the welding ring 60 might also help air tightness of the casing 10. Furthermore, an optical isolator 80 may be disposed on one side of the welding ring 60 for confining light emitted by the optical communication unit 320 to travel in a predetermined direction. An optical lens 90 may be disposed on the cap 120 of the casing 10 for converging the light emitted by the optical communication unit 320, thereby enhancing optical coupling efficiency.

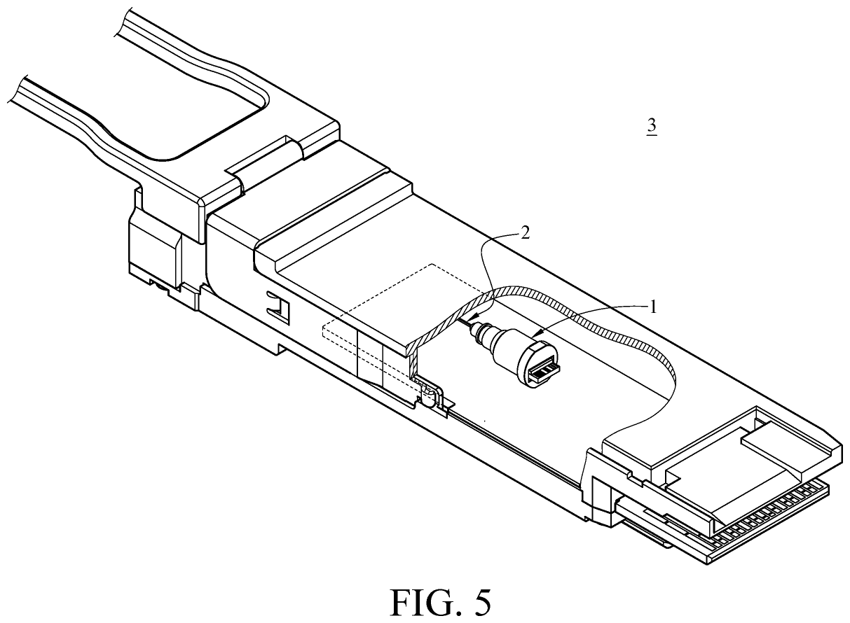

FIG. 5 is a schematic view of an optical transceiver module according to another embodiment of the present disclosure. In this embodiment, an optical transceiver module 3 includes a housing and one or more optical communication assemblies in the housing. The communication assemblies in the housing of the optical transceiver module 3 may include the aforementioned optical emitting device 1 and the optical fiber 2.

According to the present disclosure, the optical communication assembly is disposed on the thermoelectric cooler. In detail, the optical communication assembly is disposed on a cold surface of the thermoelectric cooler, and a hot surface of the thermoelectric cooler is in thermal contact with the base. The thermoelectric cooler is provided to control the operating temperature of the optical communication assembly, such that the base (header for TO-CAN package) is applicable to the packaging of the light emitting components with high power and high bandwidth. The configuration of the present disclosure can facilitate the application of TO-CAN packaging in long distance and high speed optical communication equipment.

Moreover, the base of the present disclosure includes a main body and a stem extending from the basal surface of the main body. The optical communication assembly is disposed on the stem, and a normal of a supporting surface of the stem is non-parallel to a normal of the basal surface of the main body. The circuit board is disposed on the base and electrically connected with the optical communication assembly. Therefore, compared to a conventional TO-CAN package in which both the circuit board and the optical communication components are accommodated in the casing, the circuit board is positioned at a place which is originally for leads in the present disclosure, and thus the size of casing for TO-CAN package can be reduced to meet the requirement of small form factors such as QSFP among others.

The embodiments are chosen and described in order to best explain the principles of the present disclosure and its practical applications, to thereby enable others skilled in the art to best utilize the present disclosure and various embodiments with various modifications as are suited to the particular use being contemplated. It is intended that the scope of the present disclosure is defined by the following claims and their equivalents.

What is claimed is:

1. An optical emitting device, comprising:
a base comprising a main body and a stem connected with each other, the stem extending from a basal surface of the main body, and a normal of a supporting surface of the stem being non-parallel to a normal of the basal surface of the main body;
a thermoelectric cooler disposed on the supporting surface of the stem;
an optical communication assembly disposed on the thermoelectric cooler, and the thermoelectric cooler being between the optical communication assembly and the stem; and
a circuit board disposed on the base, the circuit board passing through the main body and electrically connected with the optical communication assembly.

2. The optical emitting device according to claim 1, wherein the base is a header for TO-CAN package.

3. The optical emitting device according to claim 1, wherein the normal of the supporting surface of the stem is orthogonal to the normal of the basal surface of the main body.

4. The optical emitting device according to claim 1, wherein the circuit board passes through an opening of the main body of the base.

5. The optical emitting device according to claim 4, further comprising a solder in the opening, and the circuit board is fixed to the base by the solder.

6. The optical emitting device according to claim 1, wherein the thermoelectric cooler comprises a thermoelectric component and a chip temperature controller, the thermoelectric component comprises a cold surface and a hot surface opposite to each other, the chip temperature controller is disposed on the cold surface, and the hot surface is in thermal contact with the supporting surface of the stem.

7. The optical emitting device according to claim 6, wherein a normal of the cold surface of the thermoelectric component is parallel to the normal of the supporting surface of the stem.

8. The optical emitting device according to claim 1, wherein the optical communication assembly comprises a submount and an optical communication unit disposed on the submount, and the submount is in thermal contact with the thermoelectric cooler.

9. The optical emitting device according to claim 1, wherein the circuit board includes a ceramic PCB.

10. The optical emitting device according to claim 9, further comprising a solder, wherein the circuit board comprises a ceramic substrate and an interlayer substrate electrically insulated from each other, the solder is filled between the circuit board and the main body, and the solder is in electrical contact with the ceramic substrate.

11. An optical emitting device, comprising:
a base comprising a main body and a stem connected with each other, the stem extending from a basal surface of the main body, and a normal of a supporting surface of the stem being non-parallel to a normal of the basal surface of the main body;
a thermoelectric cooler disposed on the supporting surface of the stem, wherein the thermoelectric cooler comprises a cold surface and a hot surface opposite to each other, the hot surface is in thermal contact with the supporting surface of the stem, and a normal of the cold surface of the thermoelectric cooler is parallel to the normal of the supporting surface of the stem; and
an optical communication assembly disposed on the cold surface of the thermoelectric cooler.

12. The optical emitting device according to claim 11, wherein the base is a header for TO-CAN package.

13. The optical emitting device according to claim 11, wherein the normal of the supporting surface of the stem is orthogonal to the normal of the basal surface of the main body.

14. The optical emitting device according to claim 11, further comprising a circuit board disposed on the base, wherein the circuit board passes through the main body and is electrically connected with the optical communication assembly.

15. The optical emitting device according to claim 14, wherein the circuit board passes through an opening of the main body of the base.

16. The optical emitting device according to claim 15, further comprising a solder in the opening, and the circuit board is fixed to the base by the solder.

17. The optical emitting device according to claim 16, wherein the circuit board comprises a ceramic substrate and an interlayer substrate electrically insulated from each other, and the solder is in electrical contact with the ceramic substrate.

18. The optical emitting device according to claim 14, wherein the circuit board includes a ceramic PCB.

19. The optical emitting device according to claim 11, wherein the optical communication assembly comprises a submount and an optical communication unit disposed on the submount, and the submount is in thermal contact with the cold surface of the thermoelectric cooler.

20. An optical transceiver module, comprising the optical emitting device according to claim 1.
